(19) United States
(12) Patent Application Publication
(10) Pub. No.: US 2024/0429685 A1
(43) Pub. Date: Dec. 26, 2024

(54) Interband Cascade Lasers with Improved Voltage Efficiency

(71) Applicant: The Board of Regents of the University of Oklahoma, Norman, OK (US)

(72) Inventor: Rui Q. Yang, Norman, OK (US)

(21) Appl. No.: 18/746,971

(22) Filed: Jun. 18, 2024

Related U.S. Application Data
(60) Provisional application No. 63/509,697, filed on Jun. 22, 2023.

(51) Int. Cl. H01S 5/343; H01S 5/30; H01S 5/34

(52) U.S. Cl. CPC H01S 5/34386; H01S 5/305; H01S 5/3401

(57) ABSTRACT

An ICL has (1) an IC region having a real refractive index, the IC region configured to generate light based on interband transitions, (2) an outer cladding layer formed from a high-doped semiconductor material and having an outer cladding layer real refractive index which is lower than the IC region real refractive index, and (3) a metal contact to the outer cladding region. The ICL may further include an intermediate cladding layer positioned between the IC region and the outer cladding layer, and at least one SCL positioned between the IC region and the intermediate cladding layer. In one non-limiting embodiment the ICL comprises an outer cladding layer positioned on a p-type GaSb substrate, wherein the high-doped semiconductor material comprises n⁺-type InAsSb doped with silicon and the GaSb substrate is doped with beryllium or zinc. The ICL may instead comprise a semi-insulating substrate such as GaAs, Si, or InP.

### CROSS-REFERENCE TO RELATED APPLICATIONS

This claims priority to U.S. Prov. Patent App. No. 63/509,697 filed on Jun. 22, 2023, which is expressly incorporated herein by reference in its entirety.

### STATEMENT REGARDING FEDERALLY SPONSORED RESEARCH OR DEVELOPMENT

This invention was made with government support under NSF (ECCS-1931193) awarded by the National Science Foundation (NSF). The government has certain rights in the invention.

### BACKGROUND

In the decades since the original proposal of the interband cascade laser (ICL), a multitude of developments have paved the way for this III—V based technology to produce efficient and coherent mid-infrared (IR) light sources. Operating in a wide range of wavelengths from below 3 μm to above 13 μm, ICLs based on the type-II quantum well (QW) active region have stimulated many technological applications including gas/chemical sensing, imaging, and industrial process control.

Currently, the main approach to make ICL devices is to grow the ICL structure on n-type GaSb substrates [1-2], especially for the 3-4 μm wavelength region. This is because these ICLs employ n-type InAs/AlSb superlattice (SL) cladding layers. However, the metal contact to n-type GaSb semiconductor is not an ideal ohm contact and may cause an extra voltage on the contact. Additionally, the conduction band edge of GaSb is much higher in energy than the conduction band edge of InAs, which could cause some complications for carrier transport if the connection between them is not managed well due to possible variations of layer thicknesses in design and actual material growth. Another scenario is to grow an ICL structure on a semi-insulating substrate such as silicon (Si) substrate to obtain a large size and reduce the cost [3]. However, in the case with a Si substrate, the current needs to be injected laterally through a metal contact on the cladding layer, which is typically made of an InAs/AlSb SL layer that has a relatively high electric resistance. An improved ICL with a reduced threshold voltage and operating voltage would provide a device with improved voltage efficiency. It is to such a device that the present disclosure is directed.

### BRIEF DESCRIPTION OF THE DRAWINGS

FIG. 1 is a schematic diagram of the overall structure showing the various segments and the interband cascade region, including thin connection regions (hatched) between them.

FIG. 2 is a schematic diagram showing an ICL structure on a p-type GaSb substrate with a metal contact attached to the underside (back) of the substrate.

FIG. 3 a schematic band diagram and layer structure of an interband cascade stage, where the thickness (in unit of Å) of each layer in one stage beginning at the barrier separating the electron injector and the active region is 25, 16.5, 28, 14, 12, 32, 12, 48, 21, 41, 12, 33, 12, 27, 12, 22, 12, 19, 12 and 16.5.

FIG. 4 shows pulsed lasing spectra of an ICL from wafer Y088L at various temperatures.

FIG. 5 shows continuous wave (cw) lasing spectra of an ICL from wafer Y088L at various temperatures.

FIG. 6 shows pulsed lasing spectra of an ICL from wafer Y089L at various temperatures.

FIG. 7 shows cw lasing spectra of an ICL from wafer Y089L at various temperatures.

FIG. 8 is a schematic illustration of the overall ICL structure including a metal contact.

### DETAILED DESCRIPTION

Disclosed herein are GaSb-based ICLs with an advanced waveguide structure having improved device performance in terms of reduced threshold voltage and low threshold current densities. The novel, increased efficiency ICLs use a highly doped n⁺-InAsSb layer as the bottom outer cladding layer and are grown upon a p-type GaSb substrate, or on a semi-insulating substrate such as a Si substrate, but with a metal contact on the highly doped n⁺-InAsSb bottom cladding layer. As such, the threshold voltage and operating voltage of the ICL is reduced with improved voltage efficiency. In certain embodiments, the ICLs were able to lase at temperatures above 270 K in continuous wave (cw) mode, and above 400 K in pulsed mode.

Before further describing various embodiments of the apparatus, component parts, and methods of the present disclosure in more detail by way of exemplary description, examples, and results, it is to be understood that the embodiments of the present disclosure are not limited in application to the details of apparatus, component parts, and methods as set forth in the following description. The embodiments of the apparatus, component parts, and methods of the present disclosure are capable of being practiced or carried out in various ways not explicitly described herein. As such, the language used herein is intended to be given the broadest possible scope and meaning; and the embodiments are meant to be exemplary, not exhaustive. Also, it is to be understood that the phraseology and terminology employed herein is for the purpose of description and should not be regarded as limiting unless otherwise indicated as so. Moreover, in the following detailed description, numerous specific details are set forth in order to provide a more thorough understanding of the disclosure. However, it will be apparent to a person having ordinary skill in the art that the embodiments of the present disclosure may be practiced without these specific details. In other instances, features which are well known to persons of ordinary skill in the art have not been described in detail to avoid unnecessary complication of the description. While the apparatus, component parts, and methods of the present disclosure have been described in terms of particular embodiments, it will be apparent to those of skill in the art that variations may be applied to the apparatus, component parts, and/or methods and in the steps or in the sequence of steps of the method described herein without departing from the concept, spirit, and scope of the inventive concepts as described herein. All such similar substitutes and modifications apparent to those having ordinary skill in the art are deemed to be within the spirit and scope of the inventive concepts as disclosed herein.

The following abbreviations may be used:
A: ampere(s)
Å: angstrom(s)
AlSb: aluminum antimonide
AlSbAs: aluminum antimony arsenide
BA: broad area
CB: conduction band
cm²: centimeter(s) square
cm⁻²: inverse centimeter(s) square
cw: continuous wave
GaAs: gallium arsenide
GaInSb: gallium indium antimonide
GaSb: gallium antimonide
I: injection current
IC: interband cascade
ICL: interband cascade laser
InAs: indium arsenide
InAsSb: indium arsenic antimonide
InP: Indium phosphide
IR: infrared
Jₜₕ: threshold current density
K: Kelvin
kHz: kilohertz
LED: light-emitting diode
mA: milliampere(s)
MBE: molecular beam epitaxy
mm: millimeter(s)
mW: milliwatt(s)
nm: nanometer(s)
NSF: National Science Foundation
QW: quantum well
W-QW: “W”-quantum well
SCL: separate confinement layer
Si: silicon
SL: superlattice
SLED: super luminescent light-emitting diode
T: temperature
Te: tellurium
V: volt(s)
VB: valence band
V^{th}: threshold voltage
μm: micrometer(s)
° C.: degrees(s) Celsius

All patents, published patent applications, and non-patent publications referenced or mentioned in any portion of the present specification are indicative of the level of skill of those skilled in the art to which the present disclosure pertains, and are hereby expressly incorporated by reference in their entirety to the same extent as if the contents of each individual patent or publication was specifically and individually incorporated herein.

Unless otherwise defined herein, scientific and technical terms used in connection with the present disclosure shall have the meanings that are commonly understood by those having ordinary skill in the art. Further, unless otherwise required by context, singular terms shall include pluralities and plural terms shall include the singular.

As utilized in accordance with the methods and compositions of the present disclosure, the following terms and phrases, unless otherwise indicated, shall be understood to have the following meanings: The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or when the alternatives are mutually exclusive, although the disclosure supports a definition that refers to only alternatives and “and/or.” The use of the term “at least one” will be understood to include one as well as any quantity more than one, including but not limited to, 2, 3, 4, 5, 6, 7, 8, 9, 10, 15, 20, 30, 40, 50, 100, or any integer inclusive therein. The phrase “at least one” may extend up to 100 or 1000 or more, depending on the term to which it is attached; in addition, the quantities of 100/1000 are not to be considered limiting, as higher limits may also produce satisfactory results. In addition, the use of the term “at least one of X, Y and Z” will be understood to include X alone, Y alone, and Z alone, as well as any combination of X, Y and Z.

As used in this specification and claims, the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AAB, BBC, AAABCCCC, CBBAAA, CABABB, and so forth. The skilled artisan will understand that typically there is no limit on the number of items or terms in any combination, unless otherwise apparent from the context.

Throughout this application, the terms “about” or “approximately” are used to indicate that a value includes the inherent variation of error for the apparatus, composition, or the methods or the variation that exists among the objects, or study subjects. As used herein the qualifiers “about” or “approximately” are intended to include not only the exact value, amount, degree, orientation, or other qualified characteristic or value, but are intended to include some slight variations due to measuring error, manufacturing tolerances, stress exerted on various parts or components, observer error, wear and tear, and combinations thereof, for example. The terms “about” or “approximately”, where used herein when referring to a measurable value such as an amount, percentage, temporal duration, and the like, is meant to encompass, for example, variations of +20% or +10%, or +5%, or +1%, or +0.1% from the specified value, as such variations are appropriate to perform the disclosed methods and as understood by persons having ordinary skill in the art. As used herein, the term “substantially” means that the subsequently described event or circumstance completely occurs or that the subsequently described event or circumstance occurs to a great extent or degree. For example, the term “substantially” means that the subsequently described event or circumstance occurs at least 90% of the time, or at least 95% of the time, or at least 98% of the time.

As used herein any reference to “one embodiment” or “an embodiment” means that a particular element, feature, structure, or characteristic described in connection with the embodiment is included in at least one embodiment. The appearances of the phrase “in one embodiment” in various places in the specification are not necessarily all referring to the same embodiment.

As used herein, all numerical values or ranges include fractions of the values and integers within such ranges and fractions of the integers within such ranges unless the context clearly indicates otherwise. Thus, to illustrate, reference to a numerical range, such as 1-10 includes 1, 2, 3, 4, 5, 6, 7, 8, 9, 10, as well as 1.1, 1.2, 1.3, 1.4, 1.5, etc., and so forth. Reference to a range of 1-50 therefore includes 1, 2, 3, 4, 5, 6, 7, 8, 9, 10, 11, 12, 13, 14, 15, 16, 17, 18, 19, 20, etc., up to and including 50, as well as 1.1, 1.2, 1.3, 1.4, 1.5, etc., 2.1, 2.2, 2.3, 2.4, 2.5, etc., and so forth. Reference to a series of ranges includes ranges which combine the values of the boundaries of different ranges within the series. Thus, to illustrate reference to a series of ranges, for example, a range of 1-1,000 includes, for example, 1-10, 10-20, 20-30, 30-40, 40-50, 50-60, 60-75, 75-100, 100-150, 150-200, 200-250, 250-300, 300-400, 400-500, 500-750, 750-1,000, and includes ranges of 1-20, 10-50, 50-100, 100-500, and 500-1,000. The range 100 units to 2000 units therefore refers to and includes all values or ranges of values of the units, and fractions of the values of the units and integers within said range, including for example, but not limited to 100 units to 1000 units, 100 units to 500 units, 200 units to 1000 units, 300 units to 1500 units, 400 units to 2000 units, 500 units to 2000 units, 500 units to 1000 units, 250 units to 1750 units, 250 units to 1200 units, 750 units to 2000 units, 150 units to 1500 units, 100 units to 1250 units, and 800 units to 1200 units. Any two values within the range of about 100 units to about 2000 units therefore can be used to set the lower and upper boundaries of a range in accordance with the embodiments of the present disclosure. More particularly, a range of 10-12 units includes, for example, 10, 10.1, 10.2, 10.3, 10.4, 10.5, 10.6, 10.7, 10.8, 10.9, 11.0, 11.1, 11.2, 11.3, 11.4, 11.5, 11.6, 11.7, 11.8, 11.9, and 12.0, and all values or ranges of values of the units, and fractions of the values of the units and integers within said range, and ranges which combine the values of the boundaries of different ranges within the series, e.g., 10.1 to 11.5.

As noted above, any numerical range listed or described herein is intended to include, implicitly or explicitly, any number or sub-range within the range, particularly all integers, including the end points, and is to be considered as having been so stated. For example, “a range from 1.0 to 10.0” is to be read as indicating each possible number, including integers and fractions, along the continuum between and including 1.0 and 10.0, that is, having a minimum value equal to or greater than 1.0 and a maximum value equal to or less than 10.0, such as, for example, 3.25 to 8.65. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. Thus, even if a particular data point within the range is not explicitly identified or specifically referred to, it is to be understood that any data points within the range are to be considered to have been specified, and that the inventor(s) possessed knowledge of the entire range and the points within the range.

Where used herein, the pronoun “we” is intended to refer to all persons involved in a particular aspect of the investigation disclosed herein and as such may include non-inventor laboratory assistants and non-inventor collaborators working under the supervision of the inventor(s).

Where used herein, the term “real refractive index” of a material refers to the real part of refractive index of the material.

The present disclosure will now be discussed in terms of several specific, non-limiting, examples and embodiments. The examples described below, which include particular embodiments, will serve to illustrate the practice of the present disclosure, it being understood that the particulars shown are by way of example and for purposes of illustrative discussion of particular embodiments and are presented in the cause of providing what is believed to be a useful and readily understood description of procedures as well as of the principles and conceptual aspects of the present disclosure.

### EXAMPLES

In two non-limiting examples (Y088L and Y089L), ICLs lased near 3.6 μm at 300 K. The two exemplary wafers comprised 6 interband cascade (IC) stages and were grown on p-type GaSb substrates. The BA (100 μm and 150 μm wide and 2 mm long) ICL devices made from the two wafers were able to lase at temperatures above 270 K in continuous wave (cw) mode, and at temperatures up to 400 K in pulsed mode. More particularly, two 6-stage ICL structures were grown on p-type GaSb substrates with carrier concentration in the range of 1-3×10¹⁷/cm³, both including the advanced waveguide design, where the layer thicknesses of the intermediate InAs/AlSb SL cladding and GaSb separate confinement layer (SCL) layers were 0.75 μm and 0.21 μm, respectively. The GaSb SCLs were doped with Te to a level of 2.7×10¹⁷ cm⁻³. The bottom n⁺-InAsSb plasmon outer cladding layer thickness was 1 μm, while the top was 0.7 μm. The doping level of the n⁺-InAs_{1-y}Sb_{y} plasmon cladding layer was 3.2×10¹⁹ cm⁻³, which makes the real part of refractive index (referred to herein as the real refractive index) significantly smaller than that of the cascade region. The value y of Sb in InAs_{1-y}Sb_{y} is chosen so that the lattice constant of InAsSb is at least approximately matched to the lattice constant of GaSb. In non-limiting embodiments, y may be in a range of 0.05-0.15, e.g., 0.09. In more particular embodiments, for example where y is defined as “about 0.09”, y may equal 0.09±10%, i.e., 0.09±1% (i.e., ±0.0009), or 0.09±2% (i.e., ±0.0018), or 0.09±3% (i.e., ±0.0027), or 0.09±4% (i.e., ±0.0036), or 0.09±5% (i.e., ±0.0045), or 0.09±6% (i.e., ±0.0054), or 0.09±7% (i.e., ±0.0063), or 0.09±8% (i.e., ±0.0072), or 0.09±9% (i.e., ±0.0081), or 0.09±10% (i.e., ±0.0090).

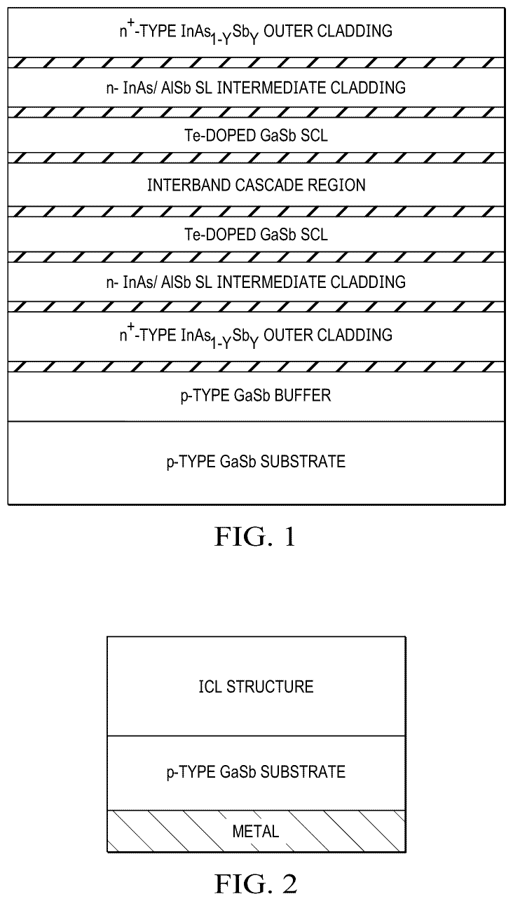

When the value y of Sb is substantially deviated from 0.09, considerable strain can be built up, which will limit the thickness of the InAs_{1-y}Sb_{y} plasmon cladding layer that could be grown without a relaxation on a GaSb substrate. Hence, in a non-limiting embodiment where y=0.09, the composition is InAs_{0.91}Sb_{0.09}, which provides a sufficiently close lattice match to the lattice constant of the GaSb substrate so that the InAs_{1-y}Sb_{y} plasmon cladding layer can be about 1 μm thick with good crystal quality. The schematic illustration of the overall ICL structure is given in FIG. 1. In an embodiment shown in FIG. 2, the ICL structure having the p-type GaSb substrate has a metal contact attached to the underside (back) of the substrate.

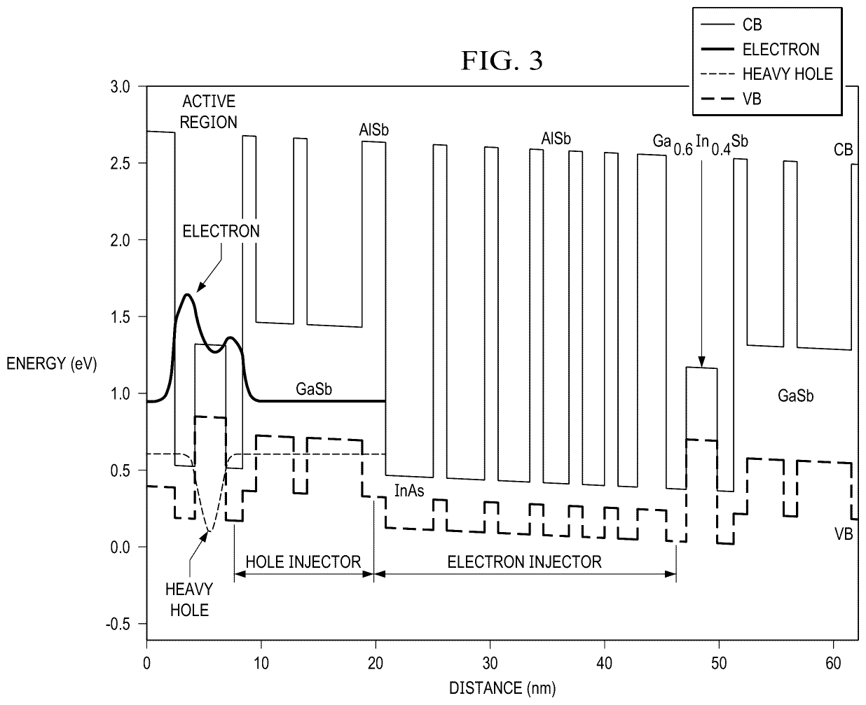

In each cascade stage of the two wafers, there is a “W”-quantum well (W-QW) active region comprising a nominally identical layer sequence of AlSb/InAs/Ga₁₋ₓInₓSb/InAs/AlSb. In non-limiting embodiments, x is in a range of 0.3-0.5, e.g., 0.4. The choice of x value is a tradeoff between the local strain and the requirement for laser performance. A higher x value in the Ga₁₋ₓInₓSb layer lowers the hole effective mass, benefiting the reduction of threshold current density, but increases the local strain, which in certain embodiments may reduce material quality and device reliability. For example, in the case where x=0.4, the W-QW active region comprises AlSb/InAs/Ga_{0.6}In_{0.4}Sb/InAs/AlSb, with layer thicknesses of 25/16.5/28/14/12 Å in the growth direction as shown in FIG. 3. The W-QW active region is sandwiched by the electron injector and hole injector. The electron injector is composed of 6 InAs/AlSb QWs, while the hole injector is composed of 2 GaSb/AlSb QWs as shown in FIG. 3. The electron injector is nominally identical for the two wafers, while the GaSb layers in the hole injector for wafer Y089L are about 10% thicker than that for wafer Y088L.

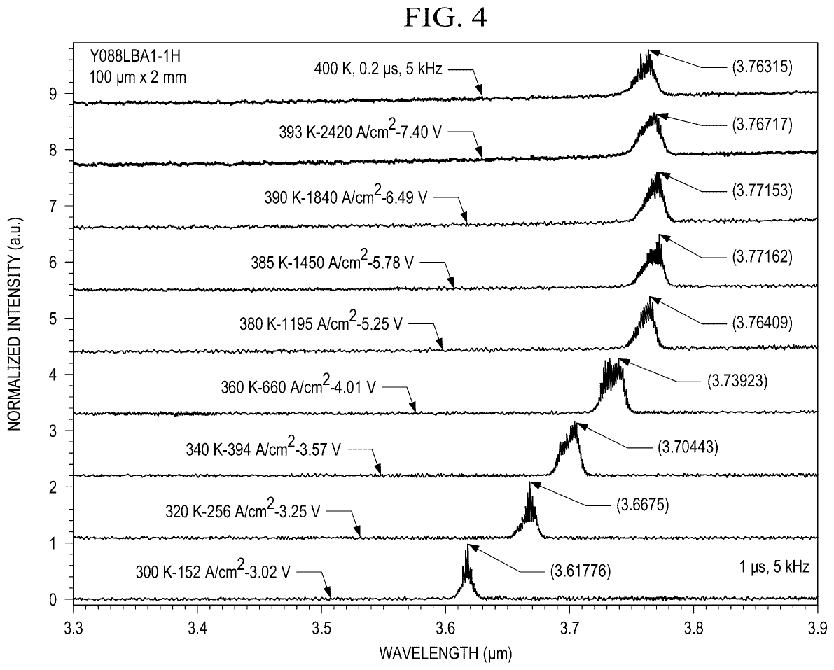

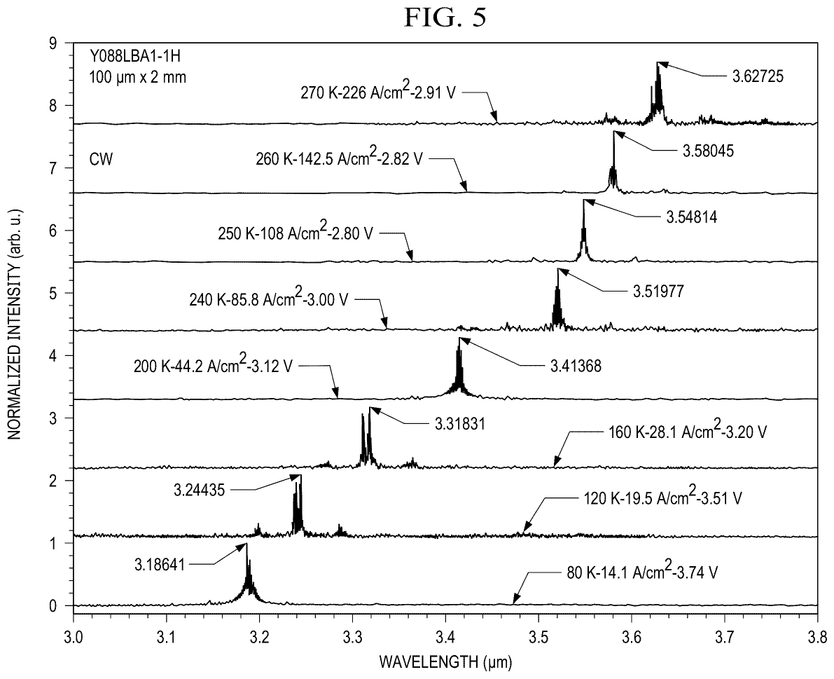

A 100-μm-wide and 2-mm-long device Y088LBA1-1H from wafer Y088L lased in pulsed modes at temperatures up to 400 K near 3.76 μm red-shifted from 3.62 μm at 300 K as shown in FIG. 4. This BA device also lased in cw up to 275 K, which is the highest reported among BA ICLs on epi-side up mounting. Its cw lasing spectra from 80 K to 270 K are shown in FIG. 5, indicating lasing wavelength shifted from 3.2 μm at 80 to 3.63 μm at 270 K. The ICL device had a threshold current density as low as 152 A/cm² at 300 K with a threshold voltage of 3.02 V. In cw operation at 270 K, the threshold current density was 226 A/cm² with a threshold voltage of 2.91 V, corresponding a voltage efficiency of 70.5%. The voltage efficiency was ˜63% at 80 K and peaked to 76% at 280 K in pulsed operation, implying smooth carrier transport.

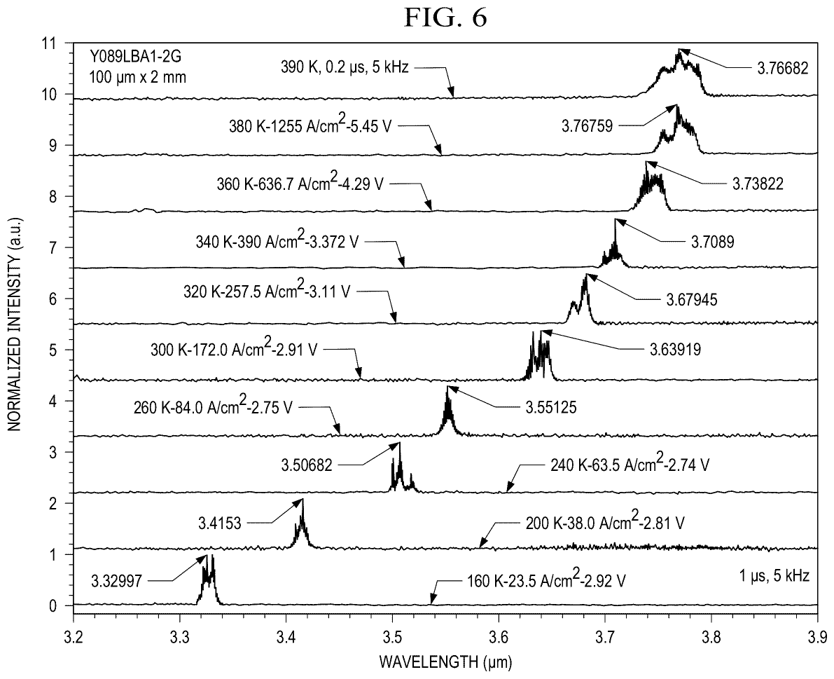

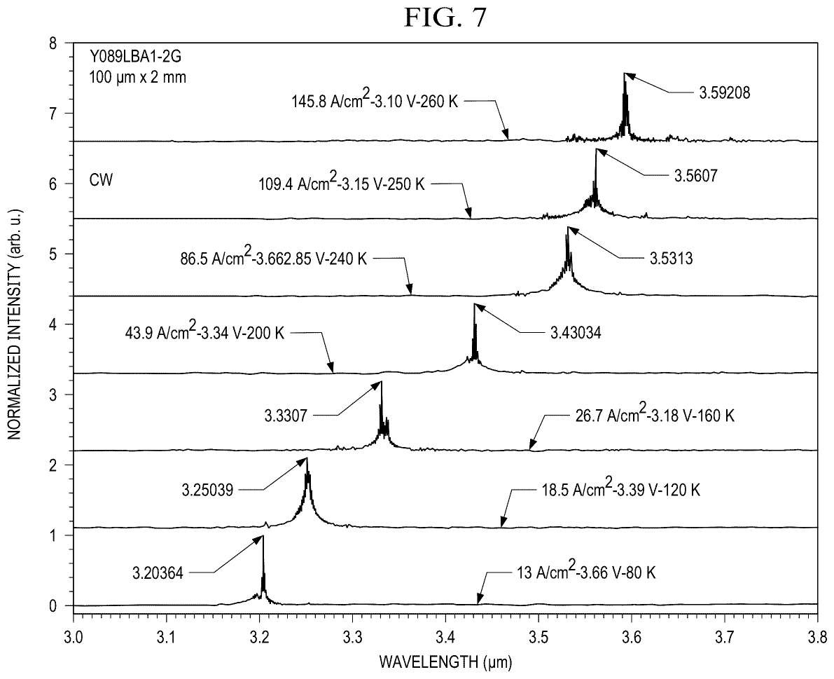

ICLs from wafer Y089L had comparable device performance with similar lasing wavelengths. The pulsed and cw lasing spectra of an ICL from wafer Y089L were shown in FIGS. 6-7, respectively. The device lased in pulsed modes up to 390 K near 3.77 μm, in cw mode up to 260 K. Compared to devices from Y088L, its threshold current density was slightly higher, but its threshold voltage was lower. The highest voltage efficiency achieved among ICLs from wafer Y089L was 78%.

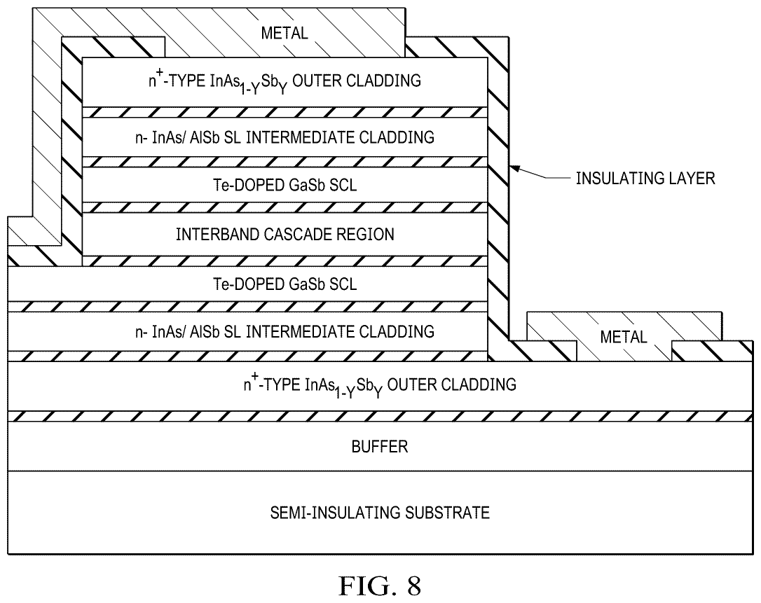

ICL structures can be grown on a semi-insulating substrate like a Si. However, the semi-insulating substrate is a poor electric conductor. To make smooth electric current injection with a minimized resistance, a configuration is shown in FIG. 7, in which the bottom n⁺-InAsSb layer not only plays a role as an outer cladding layer, but also serves as a bottom metal contact layer. Due to its high electron concentration, the electric resistance is minimized, which reduces the voltage drop across ICL devices, especially with a high current. The composition (y) of Sb in InAsSb is chosen so that the lattice constant of InAsSb is approximately matched to the lattice constant of the interband cascade region and SCL. In the example shown in FIG. 8, y is chosen to match the lattice constant of GaSb. If the cascade region is lattice matched to InAs with the InAs as the SCL, the Sb composition (y) for InAs_{1-y}Sb_{y} is zero. A high doped n⁺-InAs layer will be used for the outer cladding and metal contact layer. A buffer layer, such as shown in FIG. 1 and FIG. 8 can be used to accommodate possible lattice mismatch between the substrate and subsequent layers or/and to improve material quality. In some scenarios, the substrate may not be semi-insulating, but for certain other applications, top metal contacts are required instead of the substrate-backside metal contact shown in FIG. 2. Metals that can be used to construct the metal contacts of the present disclosure include any suitable metal known to those of ordinary skill in the art for such devices, and particularly include, but are not limited to, gold, silver, titanium, nickel, copper, platinum, palladium, and alloys thereof.

In summary, the present disclosure, is directed to, in one non-limiting embodiment, a semiconductor interband cascade (IC) laser, comprising (a) an IC region having a real refractive index and a plurality of IC stages, wherein (i) the IC region is configured to generate light based on an interband transition energy, (ii) the interband transition energy defines an emitted photon energy and a corresponding lasing wavelength, and (iii) each IC stage comprises a W-quantum well (W-QW) active region, (b) an outer plasmon cladding layer positioned below the IC region, the outer plasmon cladding layer comprising a high-doped n⁺-type InAs_{1-y}Sb_{y} semiconductor material wherein y is about 0.09 (e.g., 0.09±10%) and having an outer plasmon cladding layer real refractive index which is lower than the IC region real refractive index, and wherein the outer plasmon cladding layer has a lattice constant that is approximately matched to that of a GaSb layer, and (c) a p-type GaSb substrate positioned below and adjacent to the outer plasmon cladding layer. The W-QW active region may comprise a Ga₁₋ₓInₓSb layer, where x is in a range of 0.3-0.5, e.g., 0.4. The W-QW active region may comprise an AlSb/InAs/Ga₁₋ₓInₓSb/InAs/AlSb layer sequence, and wherein x is in a range of 0.3-0.5, e.g., 0.4. A dopant of the high-doped n⁺-type InAsSb semiconductor material of the outer plasmon cladding layer may comprise silicon. The high-doped n⁺-type InAsSb semiconductor material of the outer plasmon cladding layer may comprise a doping concentration in a range of about 1×10¹⁸ cm⁻³ to about 1×10²⁰ cm⁻³. The p-type GaSb substrate may comprise a dopant selected from beryllium and zinc. The p-type GaSb substrate may comprise a dopant in a concentration in a range of about 1×10¹⁷ cm⁻³ to about 5×10¹⁷ cm⁻³. The IC laser may comprise an intermediate cladding layer positioned between the outer plasmon cladding layer and the IC region, wherein the intermediate cladding layer comprises a first semiconductor material having an intermediate cladding layer real refractive index which is lower than the IC region real refractive index. The IC laser may further comprise at least one separate confinement layer (SCL) positioned between the IC region and the intermediate cladding layer, wherein the at least one SCL comprises a second semiconductor material having an SCL real refractive index which is greater than the intermediate cladding layer real refractive index. The SCL real refractive index may be greater than the IC region real refractive index. The second semiconductor material may be selected from the group consisting of InGaAsSb, GaSb, AlGaInSb, AlGaSbAs, and AlGaInSbAs. The intermediate cladding layer may be selected from the group consisting of a superlattice layer, a ternary semiconductor material, and a quaternary semiconductor material.

The present disclosure, is also directed to, in one non-limiting embodiment, an IC laser comprising (a) an IC region having a real refractive index, the IC region configured to generate light based on interband transitions, and having a transition energy which defines an emitted photon energy and a corresponding lasing wavelength, (b) a first outer plasmon cladding layer comprising a first high-doped n⁺-type InAs_{1-y}Sb_{y} and having a first outer plasmon cladding layer real refractive index and positioned below the IC region, wherein the first outer plasmon cladding layer real refractive index is less than the IC region real refractive index, (c) a first intermediate cladding layer positioned between the IC region and the first outer cladding layer, wherein the first intermediate cladding layer comprises a first semiconductor material having a first intermediate cladding layer real refractive index which is less than the IC region real refractive index, (d) a second outer plasmon cladding layer comprising a second high-doped n⁺-type InAs_{1-y}Sb_{y} and having a second outer plasmon cladding layer real refractive index and positioned above the IC region, and wherein the second outer plasmon cladding layer real refractive index is less than the IC region real refractive index, (e) a second intermediate cladding layer positioned between the IC region and the second outer plasmon cladding layer, wherein the second intermediate cladding layer comprises a second semiconductor material having a second intermediate cladding layer real refractive index that is less than the IC region real refractive index, and wherein the first high-doped n⁺-type InAsSb and the second high-doped n⁺-type InAsSb have lattice constants that are approximately matched to that of GaSb, and (f) a p-type GaSb substrate positioned below and adjacent to the first outer plasmon cladding layer. The IC region may comprise at least one IC stage comprising a W-quantum well (W-QW) active region. The W-QW active region may comprise a Ga₁₋ₓInₓSb layer, where x is in a range of 0.3-0.5, e.g., 0.4. The W-QW active region may comprise an AlSb/InAs/Ga₁₋ₓInₓSb/InAs/AlSb layer sequence, and wherein x is in a range of 0.3-0.5, e.g., 0.4. In the first or second high-doped n⁺-type InAs_{1-y}Sb_{y} semiconductor material, y may be about 0.09 (e.g., 0.09±10%). The IC laser may comprise a first metal contact connected to the p-type GaSb substrate. The IC laser may further comprise a second metal contact connected to the second outer cladding layer. A dopant of the first high-doped n⁺-type InAsSb or the second high-doped n⁺-type InAsSb may comprise silicon. The first high-doped n⁺-type InAsSb and/or the second high-doped n⁺-type InAsSb may comprise a doping concentration in a range of about 1×10¹⁸ cm⁻³ to about 1×10²⁰ cm⁻³. The p-type GaSb substrate may comprise a dopant selected from beryllium and zinc. The p-type GaSb substrate may comprise a dopant in a concentration in a range of about 1×10¹⁷ cm⁻³ to about 5×10¹⁷ cm⁻³. The first intermediate cladding layer and the second intermediate cladding layer may be selected from the group consisting of a superlattice (SL) layer, a ternary semiconductor material, and a quaternary semiconductor layer. The IC laser may further comprise a first separate confinement layer (first SCL) positioned between the IC region and the first intermediate cladding layer and a second separate confinement layer (second SCL) positioned between the IC region and the second intermediate cladding layer, wherein the first SCL and the second SCL each comprises at least one semiconductor material, the first SCL having a first SCL real refractive index greater than the first intermediate cladding layer real refractive index, and the second SCL having a second SCL real refractive index greater than the second intermediate cladding layer real refractive index.

The present disclosure, is also directed to, in one non-limiting embodiment, an IC laser comprising, (a) an IC region having a real refractive index, the IC region configured to generate light based on interband transitions and having a transition energy which defines an emitted photon energy and a corresponding lasing wavelength, (b) a first outer plasmon cladding layer comprising a first high-doped semiconductor material and having a first outer plasmon cladding layer real refractive index and positioned below the IC region, and wherein the first outer plasmon cladding layer real refractive index is lower than the IC region real refractive index, (c) a first intermediate cladding layer positioned between the IC region and the first outer plasmon cladding layer, wherein the first intermediate cladding layer comprises a first semiconductor material having a first intermediate cladding layer real refractive index which is lower than the IC region real refractive index, (d) a second outer plasmon cladding layer comprising a second high-doped semiconductor material and having a second outer plasmon cladding layer real refractive index and positioned above the IC region, and wherein the second outer plasmon cladding layer real refractive index is lower than the IC region real refractive index, (e) a second intermediate cladding layer positioned between the IC region and the second plasmon outer cladding layer, wherein the second intermediate cladding layer comprises a second semiconductor material having a second intermediate cladding layer real refractive index that is lower than the IC region real refractive index, (f) a substrate positioned below and adjacent to the first outer plasmon cladding layer, and (g) a first metal contact connected to the first outer plasmon cladding layer. The IC laser may further comprise a second metal contact, wherein the second metal contact is connected to the second outer cladding layer. The first and second intermediate cladding layers may be selected from the group consisting of a superlattice layer, a ternary semiconductor material, and a quaternary semiconductor material. The substrate may be a semi-insulating substrate selected from the group consisting of gallium arsenide (GaAs), silicon (Si), and indium phosphide (InP). The IC laser may further comprise a first separate confinement layer (first SCL) positioned between the IC region and the first intermediate cladding layer and a second separate confinement layer (second SCL) positioned between the IC region and the second intermediate cladding layer, said first SCL and second SCL each comprising a semiconductor material, the first SCL having a first SCL real refractive index greater than the first intermediate cladding layer real refractive index, and the second SCL having a second SCL real refractive index greater than the second intermediate cladding layer real refractive index. The semiconductor material of the first SCL and the semiconductor material of the second SCL may be selected independently from the group consisting of GaSb, InAs, InGaAsSb, AlGaInSb, AlGaSbAs, and AlGaInSbAs. The IC region may comprise at least one IC stage comprising a W-quantum well (W-QW) active region. The W-QW active region may comprise a Ga₁₋ₓInₓSb layer, wherein x is in a range of 0.3-0.5, e.g., 0.4. The first high-doped semiconductor material or the second high-doped semiconductor material may comprise an n⁺-type InAsSb or and n⁺-type InAs. The n⁺-type InAsSb may comprise InAs_{1-y}Sb_{y}, wherein y is about 0.09 (e.g., 0.09±10%). The first high-doped semiconductor material or the second high-doped semiconductor material may comprise a dopant in a concentration in a range of about 1×10¹⁸ cm⁻³ to about 1×10²⁰ cm⁻³. The first high-doped semiconductor material or the second high-doped semiconductor material may be doped with Si.

While the present disclosure has been described in connection with certain embodiments so that aspects thereof may be more fully understood and appreciated, it is not intended that the present disclosure be limited to these particular embodiments. On the contrary, it is intended that all alternatives, modifications and equivalents are included within the scope of the present disclosure. Thus the examples described above, which include particular embodiments, will serve to illustrate the practice of the present disclosure, it being understood that the particulars shown are by way of example and for purposes of illustrative discussion of particular embodiments only and are presented in the cause of providing what is believed to be the most useful and readily understood description of procedures as well as of the principles and conceptual aspects of the presently disclosed methods and compositions. Changes may be made in the compositions and structures of the various components described herein, or the methods described herein without departing from the spirit and scope of the present disclosure.

What is claimed is:

1. A semiconductor interband cascade (IC) laser, comprising:
an IC region having a real refractive index and a plurality of IC stages, wherein (1) the IC region is configured to generate light based on an interband transition energy, (2) the interband transition energy defines an emitted photon energy and a corresponding lasing wavelength, and (3) each IC stage comprises a W-quantum well (W-QW) active region;
an outer plasmon cladding layer positioned below the IC region, the outer plasmon cladding layer comprising a high-doped n⁺-type InAs_{1-y}Sb_{y} semiconductor material and having an outer plasmon cladding layer real refractive index which is lower than the IC region real refractive index, wherein y is about 0.09, and wherein the outer plasmon cladding layer has a lattice constant that is approximately matched to that of a GaSb layer; and
a p-type GaSb substrate positioned below and adjacent to the outer plasmon cladding layer.

2. The semiconductor IC laser of claim 1, wherein the W-QW active region comprises a Ga₁₋ₓInₓSb layer, where x is in a range of 0.3-0.5.

3. The semiconductor IC laser of claim 1, wherein the W-QW active region comprises an AlSb/InAs/Ga₁₋ₓInₓSb/InAs/AlSb layer sequence, and wherein x is in a range of 0.3-0.5.

4. The semiconductor IC laser of claim 1, wherein the high-doped n⁺-type InAs_{1-y}Sb_{y} semiconductor material comprises silicon as a dopant.

5. The semiconductor IC laser of claim 1, wherein the high-doped n⁺-type InAs_{1-y}Sb_{y} semiconductor material comprises a doping concentration in a range of about 1×10¹⁸ cm⁻³ to about 1×10²⁰ cm⁻³.

6. The semiconductor IC laser of claim 1, wherein the p-type GaSb substrate comprises a dopant selected from beryllium and zinc.

7. The semiconductor IC laser of claim 1, wherein the p-type GaSb substrate comprises a dopant in a concentration in a range of about 1×10¹⁷ cm⁻³ to about 5×10¹⁷ cm⁻³.

8. The semiconductor IC laser of claim 1, comprising an intermediate cladding layer positioned between the outer plasmon cladding layer and the IC region, wherein the intermediate cladding layer comprises a first semiconductor material having an intermediate cladding layer real refractive index which is lower than the IC region real refractive index.

9. The semiconductor IC laser of claim 8, further comprising at least one separate confinement layer (SCL) positioned between the IC region and the intermediate cladding layer, wherein the at least one SCL comprises a second semiconductor material having an SCL real refractive index which is greater than the intermediate cladding layer real refractive index.

10. The semiconductor IC laser of claim 9, wherein the SCL real refractive index is greater than the IC region real refractive index.

11. The semiconductor IC laser of claim 9, wherein the second semiconductor material is selected from the group consisting of InGaAsSb, GaSb, AlGaInSb, AlGaSbAs, and AlGaInSbAs.

12. The semiconductor IC laser of claim 8, wherein the intermediate cladding layer is selected from the group consisting of a superlattice layer, a ternary semiconductor material, and a quaternary semiconductor material.

13. A semiconductor interband cascade (IC) laser comprising:
an IC region having a real refractive index, the IC region configured to generate light based on interband transitions, and having a transition energy which defines an emitted photon energy and a corresponding lasing wavelength;
a first outer plasmon cladding layer comprising a first high-doped n⁺-type InAs_{1-y}Sb_{y} and having a first outer plasmon cladding layer real refractive index and positioned below the IC region, wherein the first outer plasmon cladding layer real refractive index is less than the IC region real refractive index;
a first intermediate cladding layer positioned between the IC region and the first outer plasmon cladding layer, wherein the first intermediate cladding layer comprises a first semiconductor material having a first intermediate cladding layer real refractive index which is less than the IC region real refractive index;
a second outer plasmon cladding layer comprising a second high-doped n⁺-type InAs_{1-y}Sb_{y} and having a second outer plasmon cladding layer real refractive index and positioned above the IC region, and wherein the second outer plasmon cladding layer real refractive index is less than the IC region real refractive index;
a second intermediate cladding layer positioned between the IC region and the second outer plasmon cladding layer, wherein the second intermediate cladding layer comprises a second semiconductor material having a second intermediate cladding layer real refractive index that is less than the IC region real refractive index, and wherein the first high-doped n⁺-type InAs_{1-y}Sb_{y} and the second high-doped n⁺-type InAs_{1-y}Sb_{y} have lattice constants that are approximately matched to that of GaSb; and
a p-type GaSb substrate positioned below and adjacent to the first outer plasmon cladding layer.

14. The semiconductor IC laser of claim 13, wherein the IC region comprises at least one IC stage comprising a W-quantum well (W-QW) active region.

15. The semiconductor IC laser of claim 14, wherein the W-QW active region comprises a Ga₁₋ₓInₓSb layer, where x is in a range of 0.3-0.5.

16. The semiconductor IC laser of claim 14, wherein the W-QW active region comprises an AlSb/InAs/Ga₁₋ₓInₓSb/InAs/AlSb layer sequence, and wherein x is in a range of 0.3-0.5.

17. The semiconductor IC laser of claim 13, wherein in the first high-doped n⁺-type InAs_{1-y}Sb_{y} or the second high-doped n⁺-type InAs_{1-y}Sb_{y}, y is about 0.09.

18. The semiconductor IC laser of claim 13, comprising a first metal contact connected to the p-type GaSb substrate.

19. The semiconductor IC laser of claim 18, further comprising a second metal contact, wherein the second metal contact is connected to the second outer plasmon cladding layer.

20. The semiconductor IC laser of claim 13, wherein the first high-doped n⁺-type InAs_{1-y}Sb_{y} and/or the second high-doped n⁺-type InAs_{1-y}Sb_{y} comprises silicon as a dopant.

21. The semiconductor IC laser of claim 13, wherein the first high-doped n⁺-type InAs_{1-y}Sb_{y} or the second high-doped n⁺-type InAs_{1-y}Sb_{y} comprises a doping concentration in a range of about 1×10¹⁸ cm⁻³ to about 1×10²⁰ cm⁻³.

22. The semiconductor IC laser of claim 13, wherein the p-type GaSb substrate comprises a dopant selected from beryllium and zinc.

23. The semiconductor IC laser of claim 13, wherein the p-type GaSb substrate comprises a dopant in a concentration in a range of about 1×10¹⁷ cm⁻³ to about 5×10¹⁷ cm⁻³.

24. The semiconductor IC laser of claim 13, wherein the first intermediate cladding layer and the second intermediate cladding layer are selected from the group consisting of a superlattice (SL) layer, a ternary semiconductor material, and a quaternary semiconductor layer.

25. The semiconductor IC laser of claim 13, further comprising a first separate confinement layer (first SCL) positioned between the IC region and the first intermediate cladding layer and a second separate confinement layer (second SCL) positioned between the IC region and the second intermediate cladding layer, wherein the first SCL and the second SCL each comprises at least one semiconductor material, the first SCL having a first SCL real refractive index greater than the first intermediate cladding layer real refractive index, and the second SCL having a second SCL real refractive index greater than the second intermediate cladding layer real refractive index.

26. A semiconductor interband cascade (IC) laser comprising:
an IC region having a real refractive index, the IC region configured to generate light based on interband transitions and having a transition energy which defines an emitted photon energy and a corresponding lasing wavelength;
a first outer plasmon cladding layer comprising a first high-doped semiconductor material and having a first outer plasmon cladding layer real refractive index and positioned below the IC region, and wherein the first outer plasmon cladding layer real refractive index is lower than the IC region real refractive index;
a first intermediate cladding layer positioned between the IC region and the first outer plasmon cladding layer, wherein the first intermediate cladding layer comprises a first semiconductor material having a first intermediate cladding layer real refractive index which is lower than the IC region real refractive index;
a second outer plasmon cladding layer comprising a second high-doped semiconductor material and having a second outer plasmon cladding layer real refractive index and positioned above the IC region, and wherein the second outer plasmon cladding layer real refractive index is lower than the IC region real refractive index;
a second intermediate cladding layer positioned between the IC region and the second plasmon outer cladding layer, wherein the second intermediate cladding layer comprises a second semiconductor material having a second intermediate cladding layer real refractive index that is lower than the IC region real refractive index;
a substrate positioned below and adjacent to the first outer plasmon cladding layer; and
a first metal contact connected to the first outer plasmon cladding layer.
